(19) United States
(12) Patent Application Publication
(10) Pub. No.: US 2004/0197672 A1
(43) Pub. Date: Oct. 7, 2004

(54) Programmable aperture for lithographic imaging systems

(75) Inventors: J. Tracy Weed, San Jose, CA (US); Fang-Cheng Chang, Sunnyvale, CA (US)

Correspondence Address: BEVER HOFFMAN & HARMS, LLP, 1432 CONCANNON BLVD, BLDG G, LIVERMORE, CA, 94550-6006, US

(73) Assignee: Numerical Technologies, Inc.

(21) Appl. No.: 10/405,228

(22) Filed: Apr. 1, 2003

(51) Int. Cl. G03F 7/20

(52) U.S. Cl. 430/5; 430/30; 430/322

(57) ABSTRACT

Printing very small features on a wafer may require optimizing an illumination configuration in the lithographic imaging system. In a conventional system, an aperture provides only one illumination configuration. In contrast, a programmable aperture can ensure that each mask design is printed using its optimized illumination configuration while minimizing the amount of hardware in the system. The programmable aperture can include a grid of pixels, wherein each pixel can be controlled to provided a predetermined light state. Once installed, the programmable aperture can provide any number of illumination configurations, thereby eliminating the expense of fabricating, testing, and repairing multiple apertures as well as the time associated with installing those multiple apertures.

### BACKGROUND OF THE INVENTION

1. Field of the Invention

The present invention relates to a lithographic imaging system and particularly to a programmable aperture for this system.

2. Description of the Related Art

Photolithography is a well-known process used in the semiconductor industry to form lines, contacts, and other known structures in integrated circuits (ICs). In a conventional lithographic imaging system 100 shown in FIG. 1A, a mask (or a reticle) 104 having a pattern of transparent and opaque regions representing such structures in one IC layer is illuminated using a light source 101. The emanating light from mask 104 is then focused onto a photoresist layer provided on a wafer 106. During a subsequent development process, portions of the photoresist layer are removed, wherein the portions are defined by the pattern. In this manner, the pattern of mask 104 is transferred to or printed on the photoresist layer. This pattern can then be transferred to a semiconductor layer of wafer 106 using known development and etching steps.

In general, the more light delivered to wafer 106, the shorter the exposure time, thereby allowing more ICs to be manufactured at a faster rate. Therefore, in system 100, a condenser lens 103 includes complex optical trains of concave and convex mirrors to ensure that as much light as possible from light source 101 is projected onto mask 104 in a distortion free manner. Similarly, a projection lens 105, which also includes complex optical trains, captures as much light as possible from mask 104 and then focuses the emanating light from mask 104 onto the photoresist layer on wafer 106 in a distortion free manner.

Lithographers are continuously pushing the limits of photolithography to achieve ever-smaller feature sizes, thereby increasing the number of devices and functionalities provided by the ICs. To reach this goal, resolution enhancement techniques are now frequently used if the desired feature size is less than the wavelength of light. One such resolution enhancement technique is the use of modified illumination in lithographic imaging systems.

In general, the illumination of a lithographic imaging system can be characterized as either on- or off-axis. In system 100, the illumination configuration can be modified using aperture 102. Examples of apertures providing on-axis illumination include small sigma, medium sigma, and large sigma (i.e. essentially one hole in the middle of a plate). An exemplary sigma aperture is shown by aperture 102 of FIG. 1A. Examples of apertures providing off-axis illumination include dipole (i.e. two holes), quadrupole (i.e. four holes), and annular (i.e. donut-shaped). Exemplary dipole aperture 111, quadrupole aperture 112, and annular aperture 113 are shown in an aperture set 110 of FIG. 1B.

Off-axis illumination generally improves the overall resolution capability of a lithographic imaging system. More specifically, the choice of an off-axis illumination, i.e. an illumination configuration, for a given feature can result in a dramatic increase in the depth of focus for that feature. However, off-axis illumination does not provide the same resolution improvement for both densely spaced and isolated features. Therefore, some apertures can further include auxiliary patterns to the above-described conventional configurations to provide some off-axis as well as on-axis illumination. A technique called diffraction pattern matching determines an optimized illumination (and corresponding aperture) configuration based on the mask pattern.

A conventional aperture is fabricated from metal. Other known apertures create a surface hologram by etching quartz. In this aperture, when light passes through the etched quartz, wavefronts are generated that emulate the desired illumination configuration (e.g. dipole, sigma, etc.). Articles such as “Design and Fabrication of Customized Illumination Patterns for Low-k1 Lithography—A Diffractive Approach” by Menelaos K. Poutous et al., p. 1556-1562, published by Proc. SPIE Vol. 4691 in July 2002 and “Design and Fabrication of Customized Illumination Patterns for Low-k1 Lithography: A Diffractive Approach” by Marc D. Himel, p. 1436-1442, published by Proc. SPIE Vol. 4346 in September 2001 describe this surface hologram technology. In one embodiment, multiple hardware apertures, which are typically one inch square, can be placed in a turret, i.e. a revolving holder. In this manner, a conventional lithographic imaging system can use multiple aperture configurations.

However, as mask patterns become more complex, existing aperture configurations may need to be modified. For example, one aperture configuration may need to be slightly changed, whereas another aperture configuration may need to be significantly changed to optimize the exposure of those patterns. Other newly developed mask patterns may require completely different aperture configurations. As a result, the demand for more aperture configurations continues to dramatically grow. Therefore, a need arises for a customizable aperture.

### SUMMARY OF THE INVENTION

Printing very small features on a wafer may require the use of multiple resolution enhancement techniques. One such resolution enhancement technique is providing an optimized illumination configuration. Specifically, to fully optimize the exposure of a mask and thus the printing of features on a wafer, a lithographer should have the flexibility to change an aperture configuration depending on mask pattern.

Unfortunately, only a limited number of aperture configurations are typically available. In a conventional system, each aperture provides a single aperture configuration. Thus, multiple aperture configurations require multiple apertures to be fabricated, tested, and repaired. Moreover, when a different aperture configuration is desired, one aperture must be removed and another aperture must be installed, thereby requiring a predetermined amount of time for the apertures to be switched each time a new aperture configuration is desired. Both hardware availability as well as equipment overhead can severely limit the ability of a lithographer to fully take advantage of custom illumination during printing of the wafer. Therefore, optimized feature printing is seldom achieved using a standard aperture configuration.

In accordance with one feature of the invention, an aperture can be programmed to provide a desired configuration, thereby ensuring that each design is printed using its optimized illumination configuration. This programmable aperture can replace the conventional aperture, which can only provide a single aperture configuration and thus a single illumination configuration. In contrast, once installed, the programmable aperture can provide any number of illumination configurations. In this manner, a lithographer can extract maximum performance from the system while ensuring maximum throughput to reach production goals.

The programmable aperture can include a grid of pixels, wherein each pixel can be controlled to provided a predetermined light state. The predetermined light state can be determined by transmission or an angle of reflectivity. For example, if the light state is determined by transmission, then a liquid crystal cell could implement the pixel. On the other hand, if the light state is determined by reflectivity, then a digital micro-mirror device or some other electro-mechanical device could implement the pixel.

The programmable aperture can advantageously be used in dual mask as well as single mask exposures. For example, the programmable aperture can provide different configurations when using a phase shifting mask and its corresponding trim mask. Specifically, the aperture configuration for each exposure can be finely adjusted or even completely changed to provide the optimal illumination configuration for each mask. In a dual exposure process, wafer metrology data resulting from an exposure of one mask can be analyzed before determining the optimal illumination configuration for the exposure of the other associated mask. Wafer metrology feedback can also be used on the fly during a single mask exposure. For example, after a limited number of features are printed and analyzed, the programmable aperture can be modified during the printing process (i.e. on the fly) to ensure that the remaining features on the wafer can be optimally printed.

Advantageously, a programmable aperture including a grid of pixels can easily replace the conventional hardware aperture used in a lithographic imaging system. In such a system, the grid can receive light from a light source, a condenser lens can project light from the grid onto one or more masks, and a projection lens can capture light emanating from the mask and then focus the light onto the wafer.

The programmable-aperture can be used to compensate for the undesirable effects of lens aberrations in the condenser or projection lens. All lithographic imaging systems can suffer from some lens aberrations. Such aberrations can undesirably affect image position, image symmetry, and the process window. In one embodiment, fine-tuning of the configuration of the programmable aperture can advantageously direct more or less light (i.e. energy) into appropriate parts of the aperture, thereby reducing sensitivity to aberrations. A high granularity grid allows for fine adjustments to the aperture configuration.

### BRIEF DESCRIPTION OF THE FIGURES

FIG. 1A illustrates a conventional lithographic imaging system that includes an aperture providing one illumination configuration.

FIG. 1B illustrates a set of apertures that can provide off-axis illumination.

FIG. 2A illustrates a lithographic imaging system that includes a programmable aperture to provide customizable illumination configurations.

FIGS. 2B and 2C illustrate exemplary illumination configurations that can be generated using programmable pixels, which form part of a programmable aperture.

FIG. 3 illustrates a system using twisted nematic (TN) liquid crystal (LC) cells for implementing two programmable pixels.

FIG. 4 illustrates a digital micro-mirror device (DMD) that can implement two programmable pixels. The DMD includes two exemplary micro-mirrors that can be controlled by independent tilting mechanisms.

FIG. 5 illustrates an exemplary wafer printing process that can take advantage of the benefits provided by a programmable aperture.

FIG. 6 illustrates a graph indicating an exemplary improvement in critical dimension (CD) variation by adjusting a programmable aperture before and/or during each exposure.

### DETAILED DESCRIPTION OF THE FIGURES

In accordance with one feature of the invention, a programmable aperture can be used to provide multiple illumination configurations. Specifically, the programmable aperture can provide standard on-axis illumination configurations, standard off-axis illumination configurations, as well as any customized auxiliary pattern illumination configuration. In this manner, the illumination for any mask pattern can be customized to optimize the transfer of that pattern to the wafer.

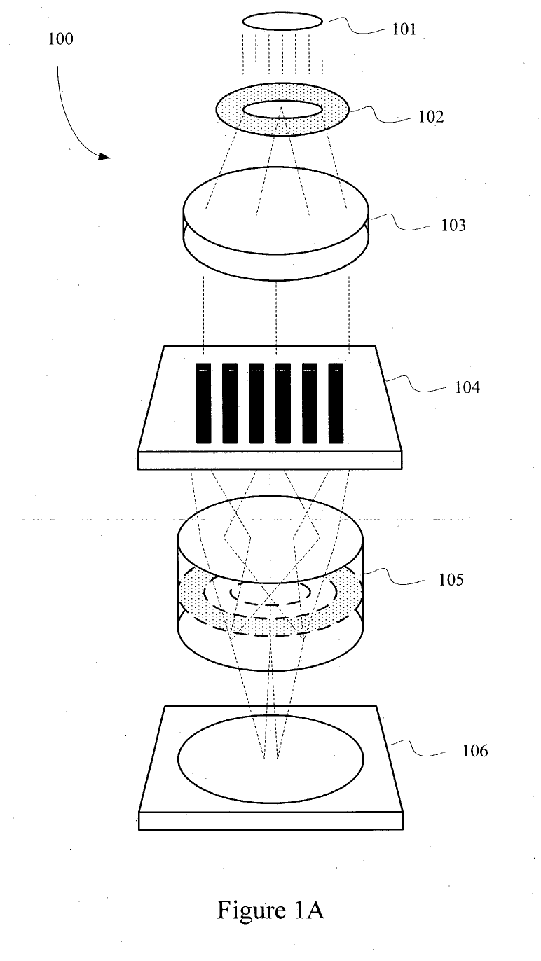

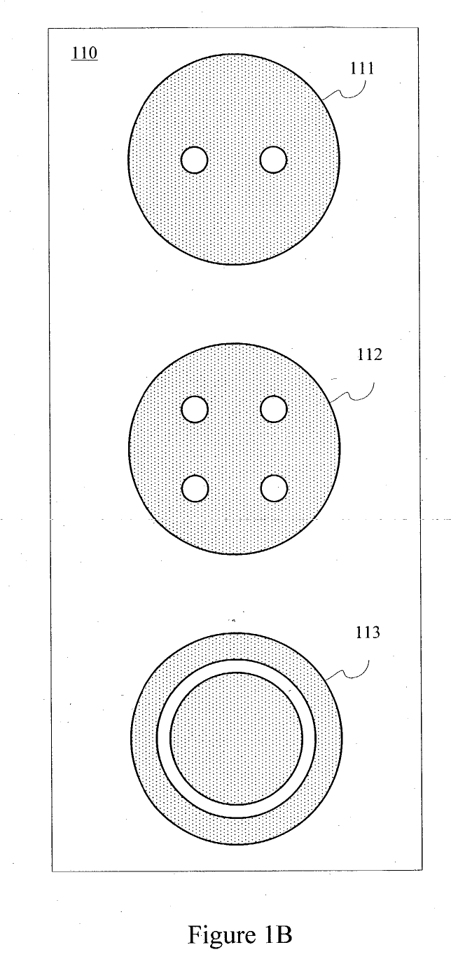

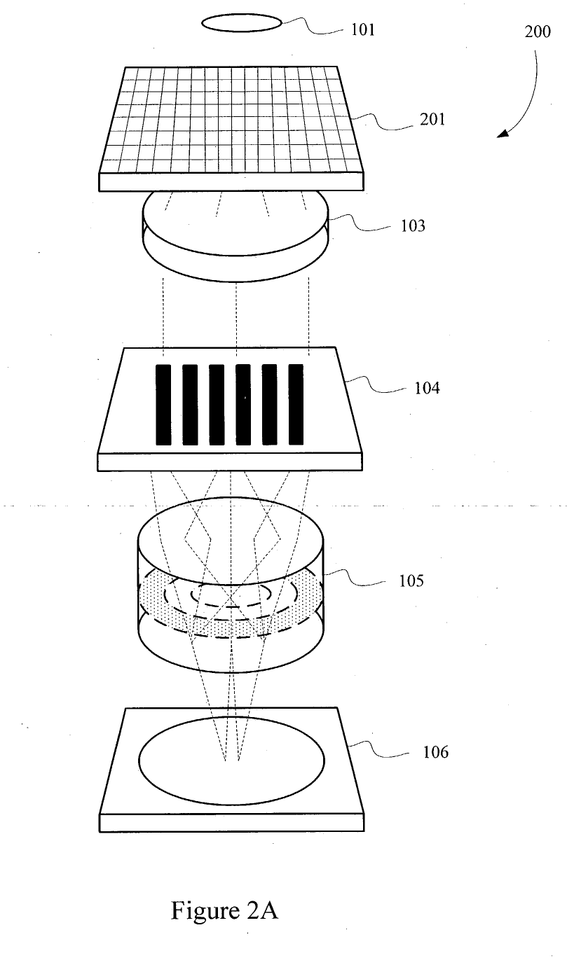

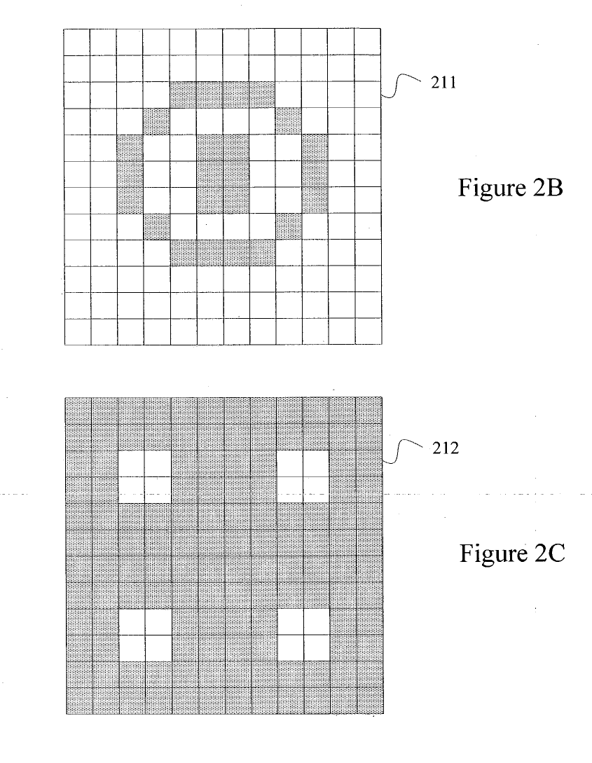

FIG. 2A illustrates a lithographic imaging system 200 that includes a programmable aperture 201 to provide customizable illumination configurations. The other components of lithographic imaging system 200 are similar to those of system 100 (FIG. 1A). Therefore, the description of those components can be found in reference to FIG. 1A.

Programmable aperture 201 can include a grid of pixels, wherein each pixel can be programmed to provide a predetermined light state. FIGS. 2B and 2C illustrate exemplary illumination configurations that can be generated using such programmable pixels. Specifically, FIG. 2B illustrates an annular illumination configuration 211, whereas FIG. 2C illustrates a quadrupole illumination configuration 212. Advantageously, these and any other illumination configurations can be provided using the same programmable grid. Note that the size of the pixels in the programmable grid effectively determines the granularity of the illumination configuration. That is, the size of the aperture can remain substantially that of a conventional aperture, e.g. an inch square. However, depending on the implementation technology, the size of the pixels can vary.

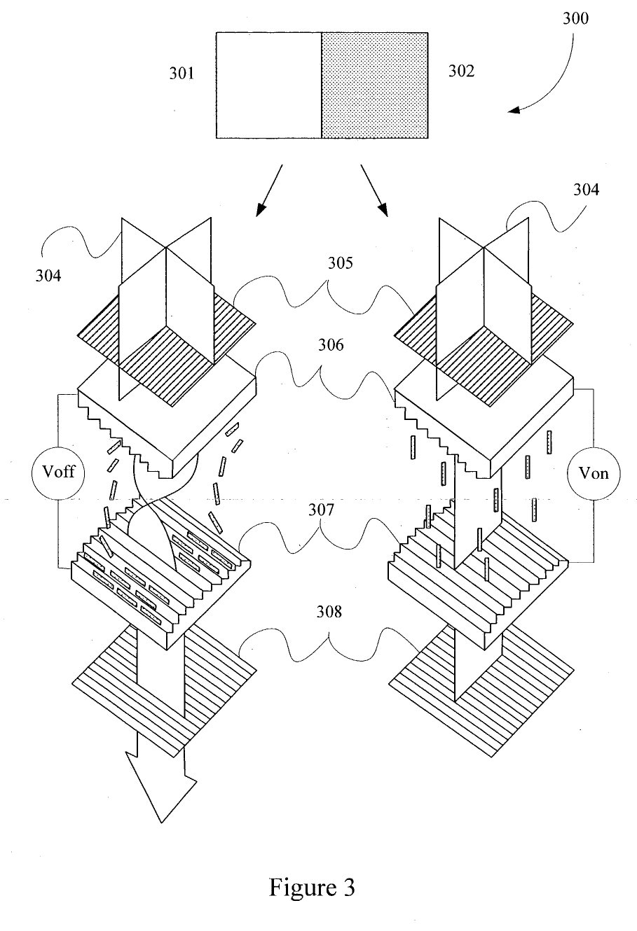

In one embodiment, the programmable aperture can be implemented using a twisted nematic (TN) type of liquid crystal (LC) cells. FIG. 3 illustrates a system 300 using TN LC cells for implementing two pixels 301 and 302. In system 300, two polarizing filters 305 and 308 are arranged such that their planes of polarization are perpendicular to each other (i.e. oriented at 90 degrees). System 300 further includes two alignment layers 306 and 307, which include electrodes coated with a thin layer of polymer brushed in one direction, thereby creating parallel ridges on the electrodes (wherein the ridges are also oriented at 90 degrees). The nematic liquid crystal molecules, which are located between alignment layers 306 and 307, tend to orient with their long axes parallel to the ridges.

In the absence of an electric field (i.e. Voff), the nematic LC molecules undergo a 90 degree twist within the cell. Thus, un-polarized light 304 would enter polarizing filter 305 and emerge polarized in the same orientation as the LC molecules in contact with alignment layer 306. At this point, the twisted arrangement of the LC molecules within the cell effectively acts as a “guide” for the light, i.e. rotating its plane of polarization by 90 degrees. In this manner, the polarized light is parallel to the plane of polarization of polarizing filter 308 and thus passes through polarizing filter 308. Therefore, pixel 301 is transparent.

When a voltage is applied to the electrodes of alignment layers 306 and 307 (i.e. Vₒₙ), the LC molecules tend to align with the resulting electric field (i.e. a vertical field) not the ridges of alignment layers 306 and 307. In this case, the orientation of the polarized light is perpendicular to the plane of polarization of polarizing filter 308 and thus does not pass through polarizing filter 308. Therefore, pixel 302 is opaque.

Note that LC cells can be sensitive to high temperatures. Therefore, using a laser to provide light 304 could require additional cooling components to ensure that the LC cells function properly. Alternatively, the power of the laser could be reduced, thereby reducing the heat generated by the laser.

In another embodiment of the invention, the programmable aperture can be implemented using electro-mechanical shutters for the pixels. Electro-mechanical shutters, although larger than LC cells, can have significantly less sensitivity to high temperatures, thereby allowing conventional lasers to be used for illumination.

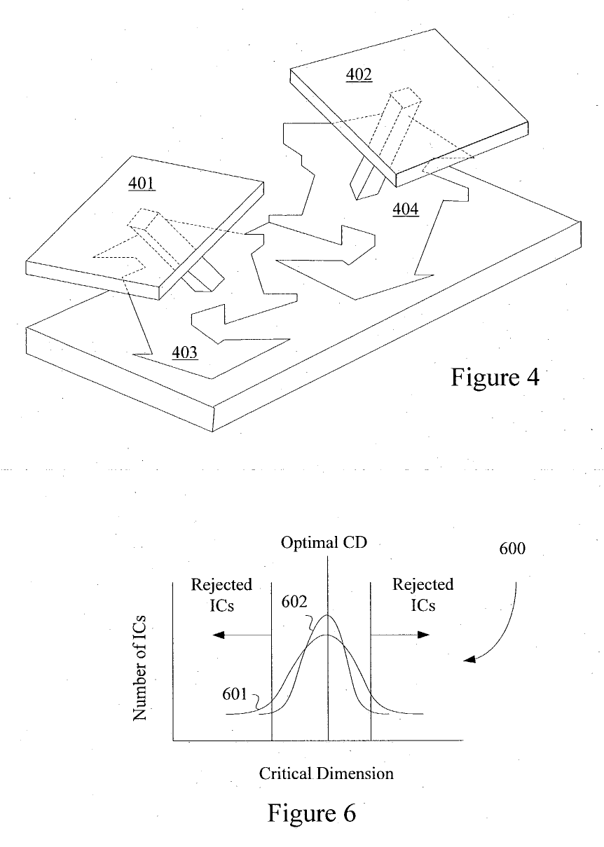

In yet another embodiment of the invention, the programmable aperture can be implemented using digital micro-mirror devices (DMDs). A DMD is an IC that can include up to a million tiny mirrors, each mirror independently controlled by its own tilting mechanism. FIG. 4 illustrates two exemplary micro-mirrors 401 and 402 controlled by tilting mechanisms 403 and 404, respectively. Mirrors 401 and 402 can tilt at two predetermined angles, e.g. 10 degrees and −10 degrees, to represent the “on” and “off” positions. Light hitting the “on” mirrors can be reflected to condenser lens 103 (FIG. 1A), whereas light hitting the “off” mirror can be reflected to a light absorber (not shown in FIG. 1A).

Advantageously, because of its reflective functionality, a DMD would absorb much less energy than an LC cell. Therefore, the DMD could transfer more energy to the mask and, as a result, to the wafer. (Note that even chemically amplified photoresists require on the order of 1-5 mJ of energy to activate pattern transfer.) Moreover, mirrors 401 and 402 each have a size of 16 um² and are typically only 1 micron apart. Therefore, a DMD can provide an aperture configuration that can be fine-tuned.

Depending on the granularity of the grid, a programmable aperture could also compensate for or at least minimize the effects of lens aberrations. Unfortunately, all lithography systems can suffer from some lens aberrations. Such aberrations can undesirably affect image position, image symmetry, and the process window. In one embodiment, fine-tuning of the configuration of the programmable aperture can advantageously direct more or less light (i.e. energy) into appropriate parts of the aperture(s), thereby reducing sensitivity to aberrations. Note that lens aberrations are typically described using Zernike polynomials, wherein each polynomial has a coefficient that quantizes a particular aspect of the aberration. In one embodiment of the invention, a set of Zernike coefficients could be used to develop an appropriate aperture configuration.

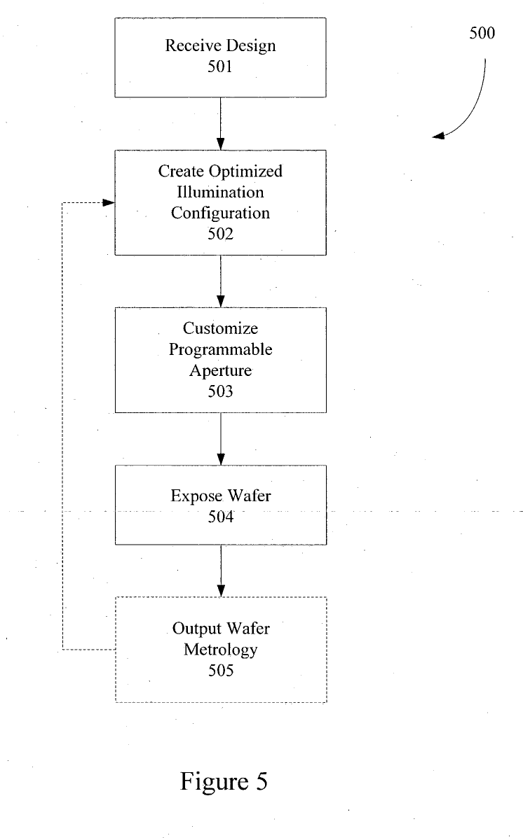

FIG. 5 illustrates an exemplary wafer printing process 500 that can take advantage of the benefits provided by a programmable aperture. In process 500, a mask design is received in step 501. The mask design can be in GDS II format, MEBES format, or any other known format. In step 502, one or more optimized illumination configurations can be created using diffraction pattern matching or some other illumination configuration computation, whether automatic or manual. In step 503, the programmable aperture can be customized based on the optimized illumination configuration. The programmable aperture can be implemented using one of the above-described technologies or with another technology allowing the transmission or reflectivity of each pixel in a grid to be set. In step 504, the wafer is exposed using a lithographic imaging system having a programmable aperture customized for the specific design to be printed. Optionally, in step 505, various wafer metrology, i.e. measurements, can be provided as feedback in process 500. This wafer metrology can be advantageously used in both dual mask and single mask exposures.

For example, the programmable aperture can provide different illumination configurations when exposing a phase shifting mask and its corresponding trim mask. In this manner, the aperture configuration for each exposure can be finely adjusted or even completely changed to provide the optimal illumination configuration for each mask. In a dual exposure process, wafer metrology data resulting from an exposure of one mask can be analyzed before determining the optimal illumination configuration for the exposure of the other associated mask.

Wafer metrology feedback can also be used on the fly during a single mask exposure. For example, this wafer metrology feedback could be used to compensate for other less than optimal exposure conditions, such as wavelength, numerical aperture, sigma, and/or exposure dose during an exposure using a single mask. Thus, after a limited number of features are printed and analyzed, the programmable aperture can be modified during the printing process to ensure that the remaining features on the wafer can be optimally printed.

With any embodiment, the programmable aperture can advantageously provides tighter critical dimension (CD) control. FIG. 6 illustrates a graph 600 indicating an exemplary improvement in CD variation by adjusting a programmable aperture before and/or during each exposure. In graph 600, curve 601 indicates the CD variation provided by one or more standard illumination configurations, whereas curve 602 indicates the CD variation provided by one or more illumination configurations using a programmable aperture. Of importance, the resulting CD variation provided by using the programmable aperture can be significantly tighter than that provided by using a conventional aperture configuration. Therefore, using the programmable aperture can advantageously improve CD control, thereby increasing the number of usable wafers.

Although illustrative embodiments of the invention have been described in detail herein with reference to the figures, it is to be understood that the invention is not limited to those precise embodiments. They are not intended to be exhaustive or to limit the invention to the precise forms disclosed. As such, many modifications and variations will be apparent.

For example, in one embodiment, the pixels of the programmable aperture can include half tone or gray scale pixels. This gradation can be achieved through the use of standard liquid crystal (LC) material, materials such as the piezoelectric transistor operating in an electric field mode, or through a mechanical means using a micro-electromechanical system (MEMS) light valve technology. These half tone pixels could be used in the creation or optimization of various devices, such as beam splitters, diffusers, beam shapers, or microlens.

In another embodiment, a programmable aperture can include asymmetrical patterns to address having multiple phase gratings on one mask. Specifically, some masks use a technique called Innovative Dual Exposure for Advanced Lithography (IDEAL) in which phase gratings can be placed on a single mask. This technique is described in an article entitled, “Multilevel Imaging System Realizing K₁=0.3 Lithography”, which was published in the Proceedings of SPIE, Optical Microlithography, 3679-36 (1999), pp. 240-251. These phase gratings can have different orientations (e.g. horizontal, vertical, 45 degrees, etc.). In such a mask, an optimized illumination configuration would typically require multiple patterns for different parts of the mask. A programmable aperture advantageously allows the pattern to be varied in any manner, thereby allowing for different illumination configurations to be provided by different parts of the aperture. Therefore, the programmable aperture provides a high degree of modularity previously not available to wafer fabrication facilities.

Note that the system and methods described herein can be applied to any lithographic process technology, including ultraviolet, deep ultraviolet (DUV), extreme ultraviolet (EUV), x-ray, and ebeam. Accordingly, it is intended that the scope of the invention be defined by the following claims and their equivalents.

1. A programmable aperture for a lithographic imaging system, the programmable aperture comprising:
a grid including a plurality of pixels, wherein each pixel can be controlled to provide a predetermined light state.

2. The programmable aperture of claim 1, wherein each pixel provides one of a transmission and an angle of reflectivity.

3. The programmable aperture of claim 1, wherein each pixel is implemented by a liquid crystal cell.

4. The programmable aperture of claim 1, wherein each pixel is implemented by a digital micro-mirror device.

5. The programmable aperture of claim 1, wherein each pixel is implemented by an electro-mechanical device.

6. The programmable aperture of claim 1, wherein the plurality of pixels are programmable to compensate for lens aberrations.

7. The programmable aperture of claim 1, wherein the plurality of pixels are programmable during a wafer exposure.

8. A lithographic imaging system comprising:
a light source for exposing a wafer;
a grid for receiving light from the light source, the grid including a plurality of pixels for providing a plurality of illumination configurations;
a condenser lens for projecting light from the grid onto a mask; and
a projection lens for capturing light from the mask and then focusing the light onto the wafer.

9. The lithographic imaging system of claim 8, wherein each pixel can be controlled to provide a predetermined light state.

10. The lithographic imaging system of claim 8, wherein each pixel provides one of a transmission and an angle of reflectivity.

11. The lithographic imaging system of claim 8, wherein each pixel is implemented by a liquid crystal cell.

12. The lithographic imaging system of claim 8, wherein each pixel is implemented by a digital micro-mirror device.

13. The lithographic imaging system of claim 8, wherein each pixel is implemented by an electro-mechanical device.

14. The lithographic imaging system of claim 8, wherein the plurality of pixels are programmable to compensate for lens aberrations.

15. The lithographic imaging system of claim 8, wherein the plurality of pixels are programmable during a wafer exposure.

16. A lithographic imaging system comprising:
illumination means for exposing a wafer;
programmable means for receiving light from the light source and providing a plurality of illumination configurations;
means for projecting light from the aperture onto a mask; and
means for capturing light from the mask and then focusing the light onto the wafer.

17. The lithographic imaging system of claim 16, wherein the programmable means includes a plurality of pixels, and wherein each pixel can be controlled to provide a predetermined light state.

18. The lithographic imaging system of claim 16, wherein the programmable means includes a plurality of pixels, and wherein each pixel provides one of a transmission and an angle of reflectivity.

19. The lithographic imaging system of claim 16, wherein the programmable means includes a plurality of pixels, and wherein each pixel is implemented by a liquid crystal cell.

20. The lithographic imaging system of claim 16, wherein the programmable means includes a plurality of pixels, and wherein each pixel is implemented by a digital micro-mirror device.

21. The lithographic imaging system of claim 16, wherein the programmable means includes a plurality of pixels, and wherein each pixel is implemented by an electro-mechanical device.

22. The lithographic imaging system of claim 16, wherein the programmable means includes a plurality of pixels, and wherein the plurality of pixels are programmable to compensate for lens aberrations.

23. The lithographic imaging system of claim 16, wherein the programmable means includes a plurality of pixels, and wherein the plurality of pixels are programmable during a wafer exposure.

24. A method of printing a wafer, the method comprising:
generating radiation from a light source;
receiving light from the light source;
programmably providing a plurality of illumination configurations using the light;
projecting a predetermined illumination configuration onto each mask used in printing the wafer; and
capturing light from each mask and focusing the light onto the wafer.

25. The method of claim 24, wherein programmably providing includes controlling individual pixels to provide predetermined light states.

26. The method of claim 25, wherein the predetermined light states are provided by one of transmission and angle of reflectivity.

27. The method of claim 25, wherein the predetermined light states are implemented by liquid crystal cells.

28. The method of claim 25, wherein the predetermined light states are implemented by digital micro-mirror devices.

29. The method of claim 25, wherein the predetermined light states are implemented by an electro-mechanical device.

30. The method of claim 24, wherein programmably providing includes compensating for lens aberrations.

31. The method of claim 24, wherein programmably providing includes changing the illumination configuration during a wafer exposure.

32. The method of claim 31, wherein changing the illumination configuration is performed after using a first mask for printing the wafer and before another mask.

33. The method of claim 24, wherein programmably providing includes creating the plurality of illumination configurations using diffraction pattern matching.

34. A method of implementing an aperture for a lithographic imaging system, the method comprising:
controlling a plurality of pixels to provide predetermined light states.

35. The method of claim 34, wherein controlling the plurality of pixels includes providing voltage to predetermined liquid crystal cells.

36. The method of claim 34, wherein controlling the plurality of pixels includes tilting digital micro-mirror devices at predetermined angles.

37. The method of claim 34, wherein controlling the plurality of pixels includes activating electro-mechanical devices.

38. The method of claim 34, wherein controlling the plurality of pixels includes compensating for lens aberrations.

39. The method of claim 34, wherein controlling the plurality of pixels includes changing the illumination configuration during a wafer exposure.

40. The method of claim 39, wherein changing the illumination configuration is performed after using a first mask for printing the wafer and before a second mask.

41. The method of claim 34, wherein controlling the plurality of pixels includes creating a plurality of illumination configurations using diffraction pattern matching.
